(19) United States
(12) Patent Application Publication
(10) Pub. No.: US 2008/0106836 A1
(43) Pub. Date: May 8, 2008

(54) IO CLAMPING CIRCUIT METHOD UTILIZING OUTPUT DRIVER TRANSISTORS

(76) Inventor: Darrin Benzer, Chandler, AZ (US)

Correspondence Address: MCANDREWS HELD & MALLOY, LTD, 500 WEST MADISON STREET, SUITE 3400, CHICAGO, IL, 60661, US

(21) Appl. No.: 11/857,873

(22) Filed: Sep. 19, 2007

Related U.S. Application Data
(63) Continuation of application No. 10/145,408, filed on May 14, 2002, now abandoned.

(51) Int. Cl. H02H 9/00; H03K 5/08

(52) U.S. Cl. 361/56; 327/321

(57) ABSTRACT

Systems and methods are disclosed for a clamping circuit for protecting against voltage overstresses. One embodiment of the system comprises a first voltage comparator adapted to detect when a selected voltage exceeds a first predetermined voltage and a second voltage comparator adapted to detect when the selected voltage falls below a second predetermined voltage, thereby preventing voltage overstresses.

### CROSS-REFERENCE TO RELATED APPLICATIONS

This application is a continuation of and claims priority to “IO Clamping circuit Method Utilizing Output Driver Transistors”, U.S. patent application Ser. No. 10/145,408, filed May 14, 2002, by Benzer. The foregoing application is incorporated herein by reference.

### FEDERALLY SPONSORED RESEARCH OR DEVELOPMENT

[Not Applicable]

### SEQUENCE LISTING

[Not Applicable]

### MICROFICHE/COPYRIGHT REFERENCE

[Not Applicable]

### BACKGROUND OF THE INVENTION

The present invention relates to a system and method for protecting sensitive circuitry from an electrical voltage overstress. More specifically, the present invention relates to a system and method for protecting sensitive circuitry from an electrical voltage overstress by employing an IO clamping circuit utilizing output driver transistors.

Many integrated circuits or ICs include bi-directional Input/Output Pads (alternatively referred to as “IO PADs” or “PADS”) coupled to the sensitive IC core logic circuitry. Such sensitive circuitry must be protected from electrical voltage overstress that appears on the IO PADs when driven by external circuitry via a bus. Known solutions have included using a variety of active or passive clamps that may occupy a large amount of silicon area. This invention attempts to utilize existing circuitry to provide voltage clamp protection against electrical voltage overstress, thereby reducing the overall die area consumed.

The problem of electrical voltage overstress becomes significantly worse when using technologies where only low voltage devices (less than about 3.0V maximum operating voltage, more specifically about 2.5V for example) are available. In addition, advancements in integrated CMOS technologies lead to smaller gate lengths and thinner oxides, thereby reducing the operating voltages of the transistors to less than or below many existing design specification requirements. One such example is the 4.6V electrical voltage overstress specified for the USB 1.1 transceiver. Some of the known active and passive clamping devices do not sufficiently protect low voltage devices under conditions as defined in such design specification requirements.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

Features of the present invention may be found in limiting the voltage seen at the IO PAD of an integrated circuit, thus preventing voltage overstress. More specifically, the present invention relates to using the output driver devices of an integrated circuit as a clamping circuit. Using the output devices as a clamping circuit limits the voltage seen at the IO PAD, thereby preventing a voltage overstress on the low voltage (2.5V for example) output transistors.

In one embodiment, a first voltage comparator detects when the PAD voltage exceeds the positive rail or VDD and sends a control signal to enable a p-channel output driver device, thereby providing a clamp to the positive rail. Conversely, if the PAD voltage falls below the negative rail or VSS, a second voltage comparator detects this condition and enables an n-channel output driver device, thereby providing a clamp to the negative rail. If the output driver devices have a sufficiently low on resistance (i.e., large current carrying capability), voltage overstress protection may be obtained while minimizing the additional die area that would otherwise be required.

An embodiment of the present invention relates to a clamping circuit adapted to prevent voltage overstress. In this embodiment, the clamping circuit comprises a comparator device adapted to detect when at least one voltage passes at least one or more voltage levels (two or more voltage levels for example). It is contemplated that, in one embodiment, the comparator device is adapted to detect when the voltage exceeds a first predetermined voltage level, and, in another embodiment, the comparator device is adapted to detect when the voltage falls below a second predetermined voltage level.

It is contemplated that the first or second voltage comparators may be separate devices or a single device adapted to detect when one or more voltages fall outside of a pre-determined range. The first voltage comparator is adapted to detect when a voltage exceeds a first predetermined voltage, while the second voltage comparator is adapted to detect when the voltage falls below a second predetermined voltage, thereby preventing voltage overstress on the devices.

One embodiment of the present invention relates to a clamping circuit for protecting against voltage overstresses. In this embodiment, the clamping circuit comprises first and second voltage comparators. The first voltage comparator is adapted to detect when a selected voltage exceeds a first predetermined voltage. The second voltage comparator is adapted to detect when the selected voltage falls below a second predetermined voltage.

It is contemplated that one embodiment of the clamping circuit may further comprise an output driver circuit adapted to be enabled by a signal transmitted by the first and/or second voltage comparators. The output driver circuit may further comprise one or more output driver devices. Said output driver device(s) may comprise a transistor device adapted to provide a path to a first voltage rail (a p-channel transistor device adapted to provide a clamp to a positive rail for example) or a path to a second voltage rail (an n-channel transistor device adapted to provide a clamp to a negative rail for example).

Yet another embodiment of the present invention relates to an integrated circuit. In this embodiment, the integrated circuit comprises a PAD and a clamping circuit. In this embodiment, the clamping circuit comprises at least one comparator device adapted to detect when at least one voltage passes one or more voltage levels, thereby preventing overstress on the PAD.

Yet another embodiment of the present invention relates to an integrated circuit comprising a PAD and a clamping circuit. In this embodiment, the clamping circuit comprises a first voltage comparator adapted to detect when a voltage exceeds a first predetermined voltage and a second voltage comparator adapted to detect when the voltage falls below a second predetermined voltage, thereby preventing a voltage overstress on the PAD.

It is contemplated that one embodiment of the integrated circuit may further comprise drive logic circuitry communicating with a data node. Moreover, the integrated circuit may comprise a pre-driver circuit, including one or more pre-drive transistor devices, communicating with at least the clamping circuit.

Yet still another embodiment of the present invention relates to an integrated circuit. In this embodiment, the circuit comprises a driver logic circuit, a pre-driver circuit communicating with at least the driver logic circuit, a PAD and a clamping circuit communicating with at least the PAD and the pre-driver circuit. Furthermore, the clamping circuit comprises a first voltage comparator adapted to detect when a PAD voltage exceeds a first predetermined voltage and a second voltage comparator adapted to detect when the PAD voltage falls below a second predetermined voltage, thereby preventing voltage overstresses on at least the PAD.

Another embodiment of the present invention relates to a method of protecting a device against voltage overstress. In this embodiment, the method comprises detecting when a voltage passes one or more voltage levels, thereby preventing voltage overstress on the device.

Yet another embodiment of the present invention relates to a method of protecting a device against voltage overstress. In this embodiment, the method comprises detecting when a voltage exceeds a first predetermined voltage, and detecting when the voltage falls below a second predetermined voltage, thereby preventing voltage overstress on the device.

Yet still another embodiment of the present invention relates to method of protecting a device against voltage overstress. In this embodiment the method comprises determining an operating range of a PAD voltage and operating the 10 PAD in a normal mode if the PAD voltage is less than a first voltage but greater than a second voltage. The method further comprises clamping the PAD voltage to a first rail if the PAD voltage is greater than a first voltage level and clamping the PAD voltage to a second rail if the PAD voltage is less than a second predetermined voltage level. In one such embodiment, the first voltage is VDD and the second voltage is VSS.

These and other advantages and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 illustrates a circuit diagram of an integrated circuit having an output stage of an IO PAD;

FIG. 2 illustrates a circuit diagram of an integrated circuit similar to that of FIG. 1 having an output stage of an IO PAD and using diodes as clamping devices;

FIG. 3 illustrates a circuit diagram of an integrated circuit similar to that of FIG. 1 having an output stage of an IO PAD and using transistor devices as clamping devices;

FIG. 4 illustrates a circuit diagram of a portion of an integrated circuit using one embodiment of a clamping circuit in accordance with the present invention;

FIG. 5 illustrates a high level flow chart of one method of protecting a device from overstress voltage in accordance with the present invention; and

FIGS. 6A and 6B illustrate a detailed flow chart of one method of protecting a device from overstress voltage in accordance with the present invention.

### DETAILED DESCRIPTION OF THE INVENTION

The following description is made with reference to the appended figures.

In accordance with one embodiment of the present invention, the output driver devices of an integrated circuit are used as a clamping circuit. Using the output driver devices as a clamping circuit limits the voltage seen at the IO PAD and prevents voltage overstresses on the low voltage (2.5V for example) devices coupled to the IO PAD.

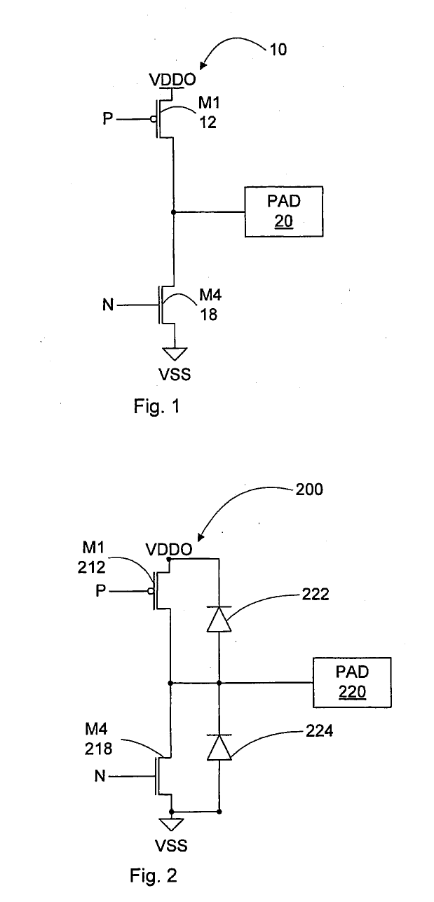

FIG. 1 illustrates a circuit 10 comprising two transistor devices, a PMOS device 12, and an NMOS device 18 coupled to output PAD 20. In this example, these devices form a sensitive tri-stated output driver circuit. One or more pre-driver devices pull the gate of device 12 up to VDDO (i.e., P=VDDO) and pull the gate of device 18 to VSS (i.e., N=VSS) to tri-state the output. It is contemplated that PAD 20 is coupled to, and may be driven by, external circuitry via a bus (not shown).

Such circuit 10 must be protected from electrical overstresses that appear on PAD 20 when driven by the external circuitry. The problems associated with electrical voltage overstresses increase as geometries decrease in advanced sub-micron technologies In one example illustrated in FIG. 1, the voltage on PAD 20 (alternatively referred to as the “PAD voltage”) may range from about −1V to about 4.6V according to the USB 1.1 specification, the complete subject matter of which is incorporated herein by reference in its entirety.

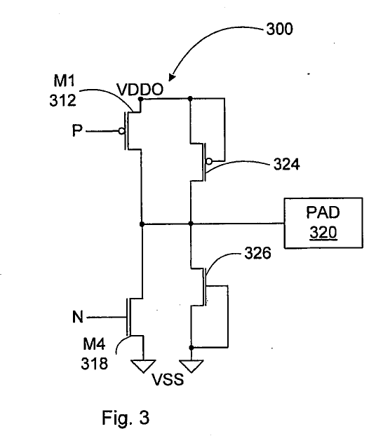

FIG. 2 illustrates circuit 200 similar to that illustrated in FIG. 1 comprising two transistor devices, a PMOS device 212, an NMOS device 218, and output PAD 220. PAD 220 is shown connected to circuit 200. Again, it is contemplated that PAD 220 is coupled to, and may be driven by, external circuitry via a bus (not shown).

FIG. 2 further illustrates one example of a known clamping device (a diode 222 having a threshold voltage or V_{D} of about 0.7V for example). In the illustrated embodiment, the PAD voltage needs to be ≧VDDO+V_{D} for the diode 222 to turn on and clamp the PAD voltage to prevent voltage overstresses. For example, if the diode V_{D}=0.7V and VDDO=3.6V then the PAD voltage must be ≧VDDO+V_{D} or 3.6V+0.7V=4.3V for the diode 222 to turn on and clamp the PAD voltage. If PAD=4.2V for example and VDDO=3.6V, then in this example, the voltage across the diode=PAD−VDDO or 4.2V−3.6V=0.6V. However, as this voltage across the diode is less than the diode threshold voltage, the diode will not turn on, and thus the clamping circuit in this example will not operate.

FIG. 2 further illustrates one example of a known clamping device (a diode 224 having a threshold voltage or V_{D} of about 0.7V for example). In the illustrated embodiment, the PAD voltage needs to be ≦VSS−V_{D} for the diode 224 to turn on and clamp the PAD voltage to prevent voltage overstresses. For example, if the diode V_{D}=0.7V and VSS=0V then the PAD voltage must be ≦VSS−V_{D} or −0.7V for the diode 224 to turn on and clamp the PAD voltage to VSS. If PAD=−0.6V for example and VSS=0V, then in this example, the voltage across the diode=−0.6V. However, as this voltage across the diode is less than the diode threshold voltage, the diode will not turn on, and thus the clamping circuit in this example will not operate.

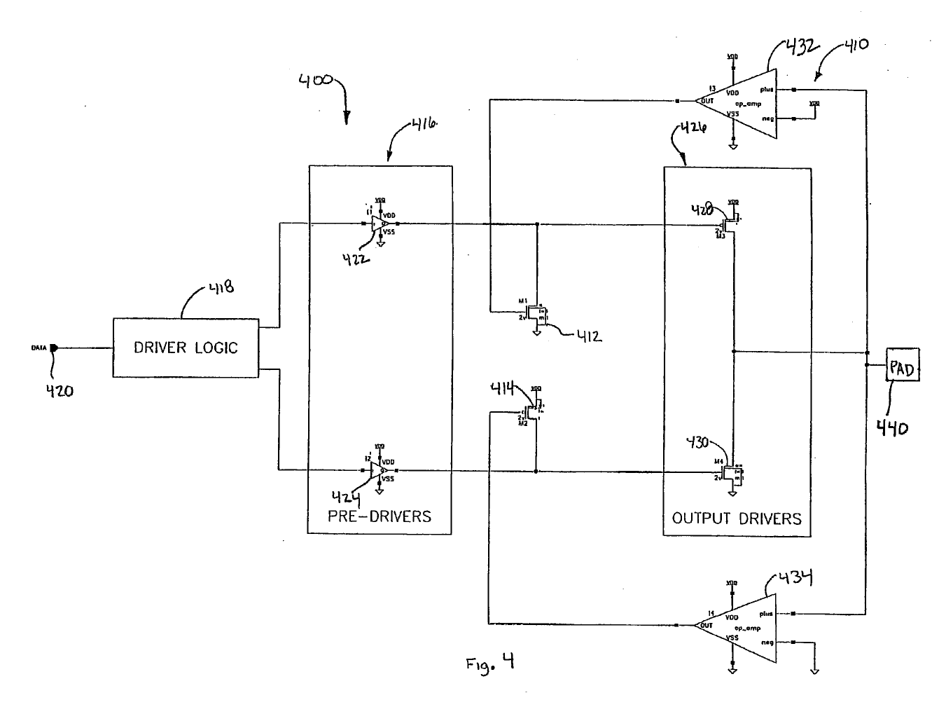

FIG. 3 illustrates circuit 300 similar to that illustrated in FIGS. 1 and 2 comprising two transistor devices, a PMOS device 312, an NMOS device 318, and output PAD 320. PAD 320 is shown connected to circuit 300. Again, it is contemplated that PAD 320 is coupled to, and may be driven by, external circuitry via a bus (not shown).

FIG. 3 further illustrates one example of a known clamping device (a PMOS transistor device 324 having a threshold voltage or V_{TP} of about 0.6V for example). In the illustrated embodiment, the PAD voltage needs to be ≧VDDO+V_{TP} for device 324 to turn on and clamp the PAD voltage to prevent voltage overstresses.

FIG. 3 further illustrates one example of a known clamping device (an NMOS transistor device 326 having a threshold voltage or V_{TN} of about 0.6V for example). In the illustrated embodiment, the PAD voltage needs to be ≦VSS−V_{TN} for device 326 to turn on and clamp the PAD voltage to prevent voltage overstresses.

Embodiments of the present invention relate to a clamping circuit comprising at least one but generally two or more voltage comparators, an integrated circuit including a clamping circuit comprising at least one but generally two or more voltage comparators and a method of protecting against electrical voltage overstresses. Integrated circuits typically include one or more IO PADS, where such IO PADS generally contain an output driver circuit comprising at least a pull-up device or a pull-down device (or some combinations thereof). Pre-driver devices may drive these pull-up and pull-down devices according to logic states generated by driver logic circuitry.

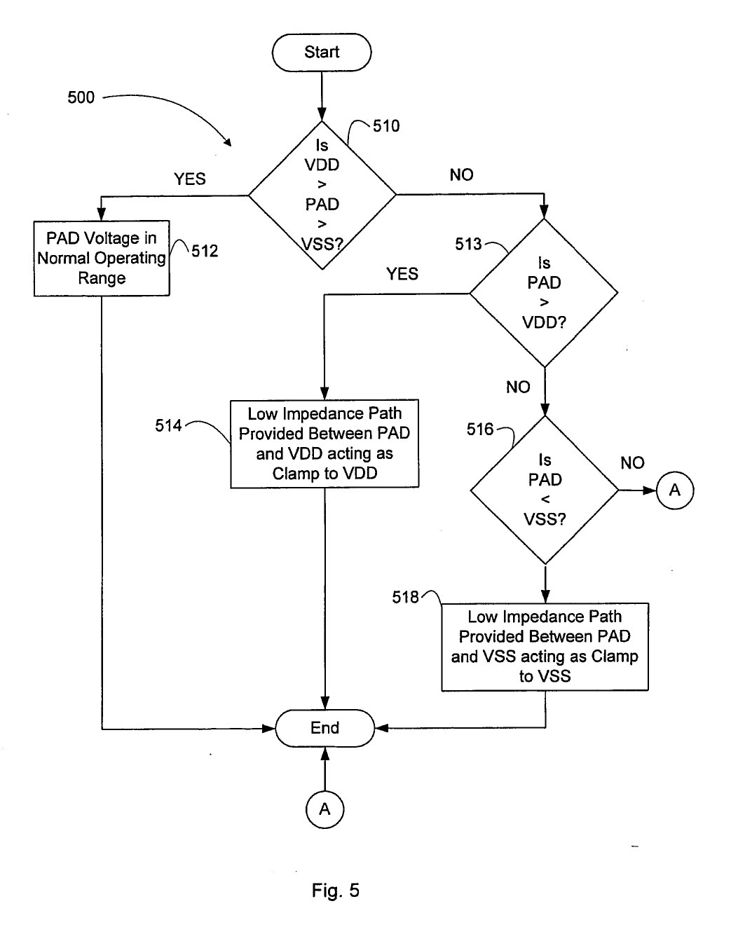

FIG. 4 illustrates a circuit diagram of a portion of an integrated circuit 400 having PAD 440 and using one embodiment of a clamping circuit 410 in accordance with the present invention. In the illustrated embodiment, the integrated circuit 400 includes one or more transistor devices, a PMOS or p-channel pull-up transistor device 414 and an NMOS or n-channel pull-down transistor device 412 (alternatively referred to as “clamping pre-drive transistor devices”). The integrated circuit 400 further comprises an output driver circuit 426 comprising two transistor devices, one PMOS or p-channel transistor device 428 and one NMOS or n-channel transistor device 430. While two devices 428 and 430 are illustrated, it is contemplated that output driver circuit 426 may comprise only one of the two illustrated devices, one device that performs the functions of the illustrated devices, both devices or some other combination (more than two devices for example).

A pre-driver circuit 416 drives devices 428 and 430 according to logic states generated by driver logic circuitry 418, which is, in one embodiment, coupled to a data node 420 of the integrated circuit. In one embodiment, the pre-driver circuit 416 comprises at least one but generally two or more pre-driver devices 422 and 424. While two devices 422 and 424 are illustrated, it is contemplated that the pre-driver circuit 416 may comprise at least one of the illustrated devices, one device that performs the functions of the illustrated devices, both devices or some other combination (i.e., more than two devices for example).

In accordance with one embodiment of the present invention, the transistor devices 412 and 414 are controlled by one or more signals that are a function of the output of the clamping circuit 410. In one embodiment, the clamping circuit 410 comprises at least one but generally two or more voltage comparators 432 and 434. The outputs of the voltage comparators 432 and 434 are used to control the clamping pre-drive transistor devices 412 and 414 respectively, which in turn are used to control the output driver transistors 428 and 430 during an overvoltage or undervoltage condition on the PAD. While two comparators and two clamping pre-drive transistors are illustrated, other embodiments are contemplated comprising one comparator device that compares one or more voltages alone or in some combination with one or more clamping pre-drive transistors, two comparator devices alone or in some combination with one or more clamping pre-drive transistors, three comparator devices alone or in some combination with one or more clamping pre-drive transistors, etc.

In one embodiment, the positive input of each comparator is connected to PAD 440 and the negative inputs of the first and second comparators 432 and 434 are connected to the positive rail (alternatively referred to as “VDD”) and the negative rail (alternatively referred to as “VSS”), respectively. The comparators may be operational at any time; however, the most critical mode of operation occurs when the output driver transistors (i.e., transistors 428 and 430) are tri-stated (i.e., in a high impedance state) and PAD is being driven by an external circuit that may potentially damage the circuitry associated with the tri-stated IO PAD.

In one embodiment, the first comparator 432 detects when the PAD voltage exceeds the positive rail (VDD) and sends a control signal to enable the p-channel output device 428 (via transistor 412 for example), thereby providing a clamp to the positive rail. Conversely, if the PAD voltage falls below the negative rail (VSS), the second comparator detects this condition and enables the n-channel output device 430 (via transistor 414 for example), thereby providing a clamp to the negative rail. If the output devices have a sufficiently low on resistance (i.e., a large current carrying capability), voltage overstress protection may be obtained while minimizing the additional die area that would otherwise be required using known clamping circuits.

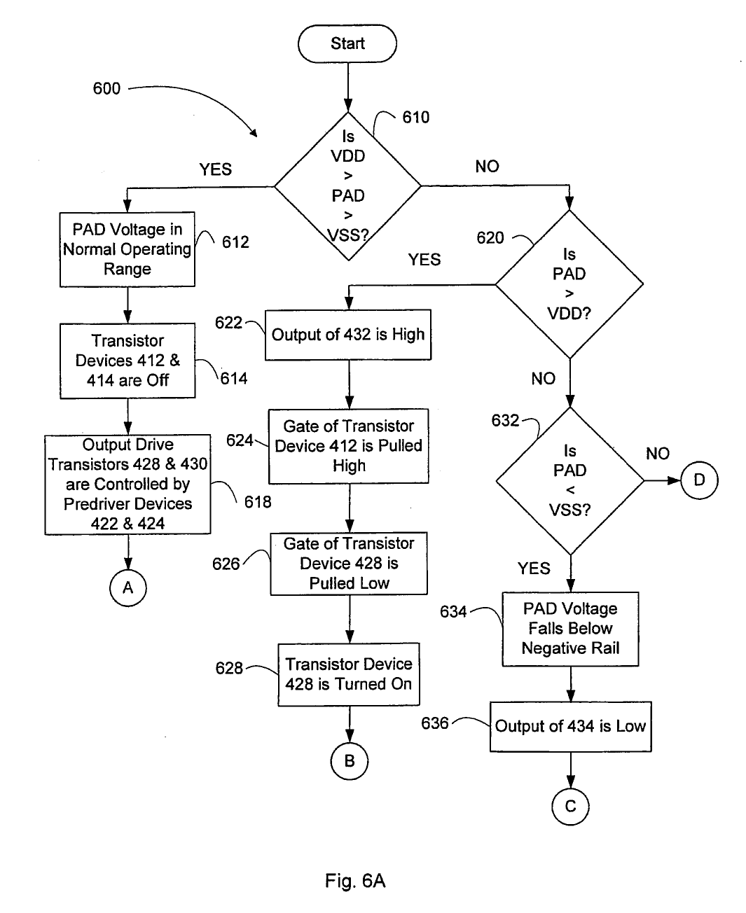

FIG. 5 illustrates a high level flow chart of one method 500 of limiting the voltage seen at the IO PAD and protecting sensitive circuitry (the output transistors in an integrated circuit for example) from overstress voltages in accordance with the present invention. It is contemplated that, in accordance with one embodiment of the present invention, if VDD>PAD>VSS as illustrated by diamond 510, the PAD voltage is within the range of normal operation as illustrated by block 512 and the clamping pre-drive transistor devices are off.

If however, PAD>VDD as illustrated by diamond 513, a low-impedance path is provided between the output or PAD and VDD, thereby acting as a clamp to VDD as illustrated by block 514. If PAD<VSS as illustrated by diamond 516, a low-impedance path is provided between the output or PAD and VSS, thereby acting as a clamp to VSS as illustrated by block 518.

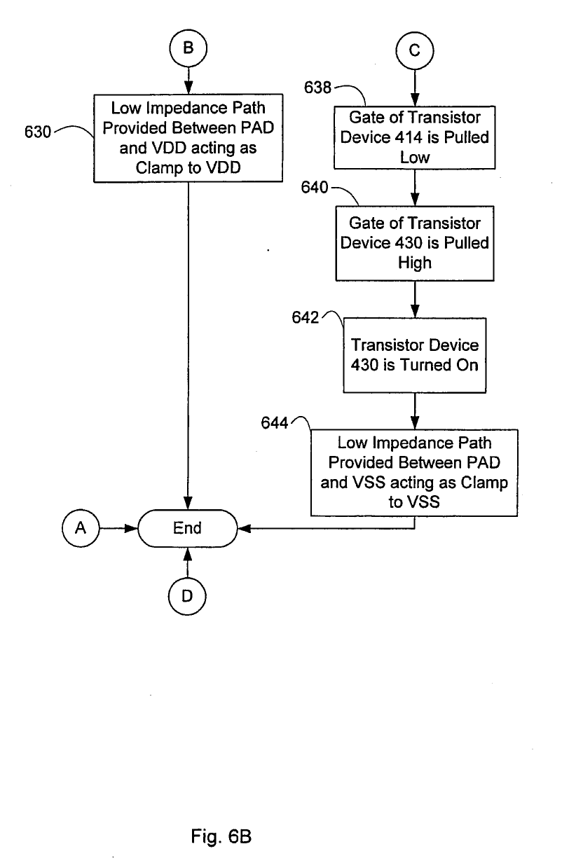

FIGS. 6A and 6B illustrate a detailed flow chart of one method 600 of protecting a device (the output transistors in an integrated circuit for example) from overstress voltages in accordance with the present invention. It is contemplated that, in one embodiment, the PAD voltage range may be divided into three regions: (1) VDD>PAD>VSS; (2) PAD>VDD; or (3) PAD<VSS.

When the PAD voltage is in the first range (i.e., when VDD>PAD>VSS as illustrated by diamond 610) the PAD voltage is in the normal operating range as illustrated by block 612. The clamping pre-drive transistor devices 412 and 414 are off as illustrated by block 614. In this range, the pre-driver devices 422 and 424 control the output driver transistors 428 and 430, as illustrated by block 618.

If the PAD voltage is not in the first region, it may be in one of the other regions. When the PAD voltage is in the second region in accordance with the present invention (i.e., PAD>VDD as illustrated by block 620), the PAD voltage exceeds the positive rail (VDD) and the output of device 432 is high as illustrated by block 622. When the output of device 432 is high, it pulls the gate of device 412 high, which then pulls the gate of the p-channel output driver 428 low as illustrated by blocks 624 and 626 respectively. Device 428 turns on as illustrated by block 628, providing a low-impedance path between the output or PAD and VDD, thereby acting as a clamp to VDD as illustrated by block 630. In this region, the output of comparator 434 is high and device 414 is off.

When the PAD voltage is in the third region (when PAD<VSS as illustrated by diamond 632), the PAD voltage falls below the negative rail and the output of 434 is low as illustrated by blocks 634 and 636 respectively. This pulls the gate of transistor device 414 low which pulls the gate of the n-channel output driver 430 high as illustrated by blocks 638 and 640. This turns transistor device 430 on as illustrated by block 642. Turning transistor device 430 on provides a low-impedance path between the output or PAD and VSS, thereby acting as a clamp to VSS as illustrated by block 644. In this region, the output of comparator 432 is low and device 412 is off.

It is contemplated that the pre-driver devices (i.e., circuits 422 and 424) may try to drive the gates of the output driver transistors to a voltage that opposes the clamping pre-drive transistor devices (i.e., transistors 412 and 414) during an overvoltage or undervoltage condition. In one embodiment of the present invention, the pre-driver devices and the clamping circuitry are not active simultaneously thus preventing the pre-driver devices from driving the gates of the output driver transistors to a voltage that opposes the clamping pre-drive transistor devices.

It is contemplated that noise may exist on the power and ground rails that may falsely activate the clamping circuit. One embodiment of the present invention includes an offset and/or hysteresis in the voltage comparators in the clamping circuit to accommodate such noise on the power and ground rails without activating the clamping circuitry. It is also contemplated that the addition of an offset and/or hysteresis in the comparators in the clamping circuit enables flexibility in adjusting the activation point of the clamping circuitry for a particular application.

It is contemplated that the clamping circuit, the integrated circuit including a clamping circuit and a method of protecting against electrical voltage overstresses in accordance with aspects of the present invention provides/includes one or more of the following advantages and features: (1) potential die area savings; (2) supplemental or complete protection against electrical voltage overstresses that appear at the IO PADs of an integrated circuit; (3) potentially eliminates the need for alternate clamping devices that tend to have higher clamping voltages and consume more die area; and (4) enables low voltage devices to be used in designs where electrical overstress voltage requirements exceed the maximum operating voltage of the low voltage devices.

Many modifications and variations of the present invention are possible in light of the above teachings. Thus, it is to be understood that, within the scope of the appended claims, the invention may be practiced otherwise than as described hereinabove.

1. A clamping circuit comprising a comparator device for detecting when at least one voltage passes at least one voltage level and an output driver circuit comprising at least one low voltage output driver device, at least said output driver device coupled to at least a bi-directional Pad providing both input and output, wherein said input is operated on by a logic core.

2. The clamping circuit of claim 1, wherein said comparator device detects when said voltage exceeds a voltage level.

3. The clamping circuit of claim 1, wherein said comparator device detects when said voltage falls below a voltage level.

4. The clamping circuit of claim 1, wherein said output driver circuit is enabled by a signal transmitted by said comparator device.

5. The clamping circuit of claim 4, wherein said output driver device provides a path to at least one voltage rail, thereby preventing voltage overstress.

6. The clamping circuit of claim 5, wherein said output driver device of said output driver circuit comprises at least one transistor device.

7. The clamping circuit of claim 1, wherein the input is a digital signal.

8. The claming circuit of claim 1, wherein the magnitude of the input is less than four volts.

9. A clamping circuit comprising:
a first voltage comparator for detecting when a voltage exceeds a first predetermined voltage; a second voltage comparator for detecting when said voltage falls below a second predetermined voltage; and
an output driver circuit enabled by a signal transmitted by at least one of said first and second voltage comparators, said output driver circuit comprising at least one low voltage output driver device, at least said one low voltage output driver device coupled to at least a bi-directional Pad providing both input and output, wherein said input is operated on by a logic core.

10. The clamping circuit of claim 9, wherein said output driver device provides a path to a voltage rail, thereby preventing voltage overstress.

11. The clamping circuit of claim 10, wherein said output driver device comprises a transistor device for providing a clamp to at least one of a positive and negative rail, thereby preventing voltage overstress.

12. The clamping circuit of claim 9, further comprising a clamping pre-drive transistor communicating with at least said first voltage comparator.

13. The clamping circuit of claim 9, further comprising a clamping pre-drive transistor communicating with at least said second voltage comparator.

14. An integrated circuit comprising:
a bi-directional PAD providing both input and output, wherein said input is a digital signal; and
a clamping circuit coupled to at least said bi-directional PAD, said clamping circuit comprising at least one comparator device for detecting when at least one voltage passes at least one voltage level.

15. An integrated circuit comprising:
a bi-directional PAD providing both input and output; and
a logic core for operating on the input from the bi-directional PAD and providing the output to the bi-directional PAD;
a clamping circuit coupled to at least said bi-directional PAD, said clamping circuit comprising:
a first voltage comparator for detecting when a voltage exceeds a first predetermined voltage; and
a second voltage comparator for detecting when said voltage falls below a second predetermined voltage.

16. The integrated circuit of claim 15, further comprising a driver logic circuit.

17. The integrated circuit of claim 15, further comprising a pre-driver circuit communicating with at least said clamping circuit.

18. The integrated circuit of claim 17, wherein said pre-driver circuit comprises at least one pre-drive device.

19. The integrated circuit of claim 15, wherein said clamping circuit further comprises an output driver circuit communicating with at least said PAD.

20. The integrated circuit of claim 19, wherein said output driver circuit is enabled by a signal transmitted by said first voltage comparator.

21. The integrated circuit of claim 19, wherein said output driver circuit is enabled by a signal transmitted by said second voltage comparator.

22. The integrated circuit of claim 19, wherein said output driver circuit comprises at least one output driver device for providing a path to a voltage rail, thereby preventing voltage overstress on said PAD.

23. An integrated circuit comprising:
a driver logic circuit;
a pre-driver circuit communicating with at least said driver logic circuit;
a bi-directional PAD providing both input and output, wherein the magnitude of the input is less than four volts; and
a clamping circuit communicating with at least said bi-directional PAD and said pre-driver circuit, said clamping circuit comprising:
a first voltage comparator for detecting when a PAD voltage of said bi-directional PAD exceeds a first predetermined voltage;
a second voltage comparator for detecting when said PAD voltage falls below a second predetermined voltage; and
an output driver circuit is enabled by a signal transmitted by said first and second voltage comparators, thereby preventing voltage overstress on at least said bi-directional PAD.

24. A method of protecting a device against voltage overstress comprising:
determining an operating range of a PAD voltage of a bi-directional PAD providing both input and output, wherein said input is operated on by a logic core in the device;
operating in a normal mode when said PAD voltage is less than a first voltage but greater than a second voltage;
clamping said voltage to a first voltage rail when said PAD voltage is greater than said first voltage; and
clamping said PAD voltage to a second rail when said PAD voltage is less than said second voltage, thereby preventing voltage overstress on the device.

25. The method of claim 24, wherein said first voltage is VDD.

26. The method of claim 24, wherein said second voltage is VSS.

27. The clamping circuit of claim 1 wherein said at least one low voltage output driver device has a maximum operating voltage of 3.0 volts or less.

28. The clamping circuit of claim 9 wherein said at least one low voltage output driver device has a maximum operating voltage of 3.0 volts or less.

29. The clamping circuit of claim 14, wherein said comparator device is for detecting when said at least one voltage exceeds a voltage level.

30. The clamping circuit of claim 14, wherein said comparator device is for detecting when said at least one voltage falls below a voltage level.

31. The clamping circuit of claim 14, further comprising an output driver circuit is enabled by a signal transmitted by said comparator device.

32. The clamping circuit of claim 31, wherein said output driver circuit comprises at least one output driver device for providing a path to at least one voltage rail, thereby preventing voltage overstress.

33. The clamping circuit of claim 32, wherein said output driver device comprises at least one low voltage transistor device.

34. The clamping circuit of claim 33 wherein said at least one low voltage transistor driver device has a maximum operating voltage 3.0 volts or less.
